(19) United States
(12) Patent Application Publication
(10) Pub. No.: US 2017/0211172 A1
(43) Pub. Date: Jul. 27, 2017

(54) EVAPORATION APPARATUS

(71) Applicants: BOE Technology Group Co., Ltd., Beijing (CN); Ordos Yuansheng Optoelectronics Co., Ltd., Inner Mongolia (CN)

(72) Inventors: Fengwei Pei, Beijing (CN); Ziyi Zhao, Beijing (CN); Fuyi Cui, Beijing (CN); Jinzhong Zhang, Beijing (CN)

(73) Assignees: BOE Technology Group Co., Ltd., Beijing (CN); Ordos Equipment Manufacturing Base, Dongsheng, Inner Mongolia (CN)

(21) Appl. No.: 15/321,442

(22) PCT Filed: Mar. 28, 2016
(86) PCT No.: PCT/CN2016/077506

§ 371 Date: Dec. 22, 2016

(30) Foreign Application Priority Data
Apr. 10, 2015 (CN) 201510169608.1

(51) Int. Cl. C23C 14/24; C23C 14/04

(52) U.S. Cl. CPC C23C 14/24; C23C 14/042

(57) ABSTRACT

An evaporation apparatus includes an evaporation chamber for evaporating a substrate to be evaporated. The evaporation chamber includes: a plurality of isolation units configured to divide the evaporation chamber into a plurality of evaporation sub-chambers; a plurality of evaporation sources respectively located in the plurality of evaporation sub-chambers; and a transportation unit arranged opposite to the evaporation sources and configured to move the substrate to be evaporated among the plurality of evaporation sub-chambers.

### CROSS-REFERENCE TO RELATED APPLICATION

This application is a Section 371 National Stage Application of International Application No. PCT/CN2016/077506, filed on Mar. 28, 2016, entitled “EVAPORATION APPARATUS”, which claims priority to Chinese Application No. 201510169608.1, filed on Apr. 10, 2015, incorporated herein by reference in their entirety.

### BACKGROUND OF THE INVENTION

Field of the Invention

Embodiments of the present disclosure relate to a technical field of manufacturing electronic components, and more particularly, to an evaporation apparatus.

Description of the Related Art

An evaporation apparatus for evaporating organic materials is generally designed to include a plurality of separate evaporation chambers and evaporation sources located in the respective evaporation chambers. It is necessary to control vacuum degree of each evaporation chamber independently, and only one material can be evaporated in each evaporation chamber. If several materials are desired to be evaporated onto a substrate, it is required to separately provide a transportation chamber so as to transport the substrate to be evaporated among the separate evaporation chambers. After the substrate to be evaporated enters into the evaporation chamber, it is necessary to vacuumize this evaporation chamber. Therefore, the conventional evaporation apparatus is relatively complex, and it is time-consuming for the evaporation apparatus to be transported and vacuumized in the prior art.

### SUMMARY OF THE INVENTION

In order to at least partially overcome the above drawbacks, embodiments of the present disclosure provide an evaporation apparatus.

The evaporation apparatus, as provided by the embodiments of the present disclosure, comprises an evaporation chamber for evaporating a substrate to be evaporated, wherein the evaporation chamber comprises: a plurality of isolation units configured to divide the evaporation chamber into a plurality of evaporation sub-chambers; a plurality of evaporation sources respectively located in the plurality of evaporation sub-chambers; and a transportation unit arranged opposite to the evaporation sources and configured to move the substrate to be evaporated among the plurality of evaporation sub-chambers.

Optionally, each of the isolation units is configured to be openable and/or closable, so as to allow one evaporation sub-chamber to be communicated with another evaporation sub-chamber adjacent thereto, the substrate to be evaporated is configured to be moved from the one evaporation sub-chamber to the another evaporation sub-chamber, which is communicated with the one evaporation sub-chamber, via the isolation unit, when the isolation unit is opened, and the evaporation sub-chambers are isolated from each other when the isolation unit is closed.

Optionally, the isolation unit comprises an upper isolation plate and a lower isolation plate, and the upper isolation plate and the lower isolation plate are configured to be at least partially overlapped with each other when the isolation unit is closed so as to isolate the one evaporation sub-chamber from the another evaporation sub-chamber adjacent thereto.

Optionally, the transportation unit comprises a magnetic plate for absorbing the substrate to be evaporated, and the magnetic plate is configured to horizontally move the substrate to be evaporated among the plurality of evaporation sub-chambers or vertically move the substrate to be evaporated in each of the evaporation sub-chambers.

Optionally, the transportation unit further comprises a plurality of supports for assisting the magnetic plate in fixing and moving the substrate to be evaporated, and the supports are arranged at two opposite sides of the magnetic plate, so as to support the substrate to be evaporated.

Optionally, the evaporation chamber further comprises a mask unit provided between the evaporation sources and the transportation unit, the mask unit being configured for selectively allowing material from the evaporation sources to pass therethrough, so as to form an evaporation pattern on the substrate to be evaporated, and the mask unit is arranged at a side of the transportation unit facing to the evaporation sources by means of a supporting rod.

Optionally, the mask unit comprises a mask and a cooling plate configured to be in contact with a side of the mask facing to the evaporation sources, the cooling plate being configured for cooling the mask and the substrate to be evaporated.

Optionally, the cooling plate comprises an opening for exposing a pattern portion of the mask.

Optionally, each of the evaporation sub-chambers comprises a shielding unit for shielding the evaporation source.

Optionally, the shielding unit comprises: a fixation plate connected to the isolation unit at a side of the evaporation sub-chamber; a shielding plate for shielding the evaporation source; and a drive shaft for connecting the fixation plate with the shielding plate and driving the shielding plate to move.

Optionally, the evaporation chamber further comprises a driving unit for driving the transportation unit to move.

Optionally, the driving unit is connected to a spindle of the magnetic plate, so as to drive the magnetic plate to move.

In the evaporation apparatus according to at least one of the embodiments of the present disclosure, the evaporation chamber includes a plurality of evaporation sub-chambers. Various layers of the substrate to be evaporated may be evaporated in the plurality of evaporation sub-chambers of the same one evaporation chamber, thereby saving the transportation time for the substrate to be evaporated. Furthermore, the evaporation chamber may be maintained in the same one vacuum environment, it is unnecessary for various evaporation sub-chambers to be separately vacuumized, thereby saving the time for the vacuumizing process.

### BRIEF DESCRIPTION OF THE DRAWINGS

FIG. 1 is a schematic front view of an evaporation apparatus according to an embodiment of the present disclosure, in which one evaporation sub-chamber (for example, a first evaporation sub-chamber) of the evaporation apparatus is in operation and being used for performing an evaporation process, and the others are not in operation;

FIG. 2 is a schematic top view of an evaporation apparatus according to an embodiment of the present disclosure, in which one evaporation sub-chamber (for example, a first evaporation sub-chamber) of the evaporation apparatus is in operation and being used for performing an evaporation process, and the others are not in operation;

FIG. 3 is a cross-section view of a transportation unit according to an embodiment of the present disclosure;

FIG. 4 is a plan view of a transportation unit according to an embodiment of the present disclosure;

FIG. 5 is a cross-section view of a mask unit according to an embodiment of the present disclosure;

FIG. 6 is a plan view of a mask unit according to an embodiment of the present disclosure;

FIG. 7 is a cross-section view of a combination of a transportation unit and a mask unit according to an embodiment of the present disclosure; and

FIG. 8 is a schematic front view of an evaporation apparatus according to an embodiment of the present disclosure, in which a plurality of evaporation sub-chambers of the evaporation apparatus is in operation and being used for performing evaporation processes.

### DETAILED DESCRIPTION OF PREFERRED EMBODIMENTS OF THE INVENTION

In order to provide a better understanding to the technical solutions of the present disclosure for the person skilled in the art, the embodiments of the present disclosure will be further described in detail below with reference to the accompanying drawings.

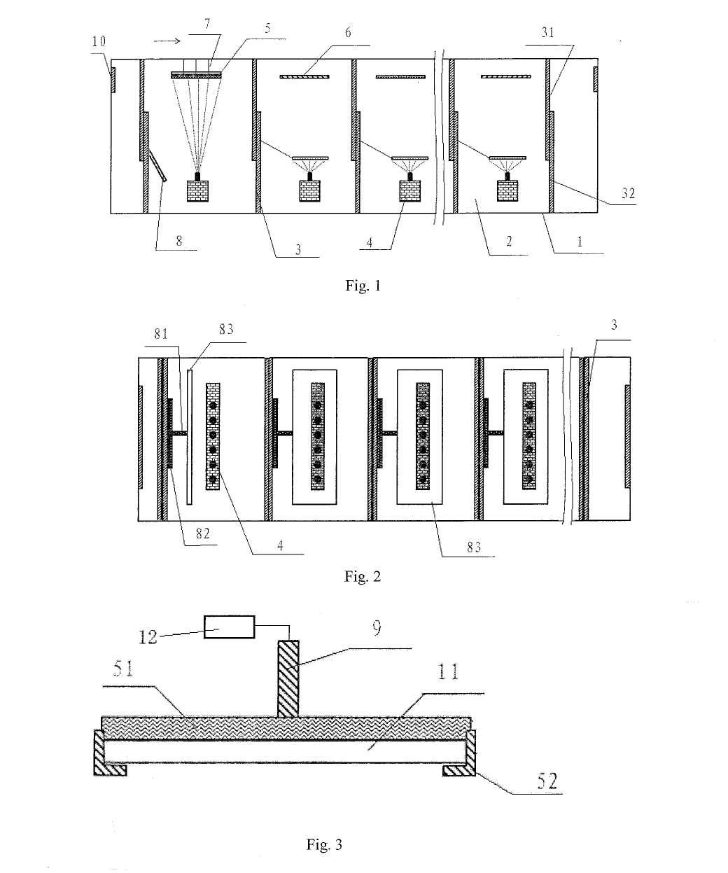

As shown in FIG. 1, an embodiment of the present disclosure provides an evaporation apparatus, including an evaporation chamber 1 for evaporating a substrate 11 to be evaporated. The evaporation chamber includes: a plurality of isolation units 3 configured to divide the evaporation chamber 1 into a plurality of evaporation sub-chambers 2; a plurality of evaporation sources 4 respectively located in the plurality of evaporation sub-chambers 2; and a transportation unit 5 arranged opposite to the evaporation sources 4 and configured to move the substrate 11 to be evaporated among the plurality of evaporation sub-chambers 2.

In the evaporation apparatus according to the embodiment of the present disclosure, the evaporation chamber includes a plurality of evaporation sub-chambers. Various layers of the substrate to be evaporated may be evaporated in the plurality of evaporation sub-chambers of the same one evaporation chamber, thereby saving the transportation time for the substrate to be evaporated. Furthermore, the evaporation chamber may be maintained in the same one vacuum environment, and it is unnecessary for various evaporation sub-chambers to be separately vacuumized, thereby saving the time for the vacuumizing process.

The evaporation apparatus according to the embodiment of the present disclosure may further have an enclosing door 10, which is located at an entrance end of the evaporation chamber 1. The substrate 11 to be evaporated may be placed in or removed from the evaporation chamber 1 through the enclosing door 10. During evaporating the substrate 11 to be evaporated, the enclosing door 10 is kept to be closed, so as to maintain the vacuum environment in the evaporation chamber 1. It should be appreciated that the evaporation chamber 1 may be provided with a vacuumizing device or a pressure buffer room, which is known to the person skilled in the art, so as to keep a stable vacuum state in the evaporation chamber 1.

As shown in FIG. 1, each of the isolation units 3 is configured to be openable and/or closable, so as to allow one evaporation sub-chamber 2 to be communicated with another evaporation sub-chamber 2 adjacent thereto. The substrate 11 to be evaporated may be moved from the one evaporation sub-chamber 2 to the another evaporation sub-chamber 2, which is communicated with the one evaporation sub-chamber 2, via the isolation unit 3, when the isolation unit 3 is opened. The evaporation sub-chambers 2 may be isolated from each other when the isolation unit 3 is closed. The isolation unit 3 may prevent the evaporation sources 4 from contaminating the adjacent evaporation sub-chamber 2 when the substrate 11 to be evaporated is being evaporated.

In one example, the isolation unit 3 is composed of an upper isolation plate 31 and a lower isolation plate 32. The upper isolation plate 31 and the lower isolation plate 32 are at least partially overlapped with each other when the isolation unit 3 is closed so as to isolate the one evaporation sub-chamber 2 from the another evaporation sub-chamber 2 adjacent thereto. It should be appreciated that the upper isolation plate 31 and the lower isolation plate 32 may be moved in a vertical direction by means of a drive device, which is known in the prior art, so as to open and/or close the isolation unit 3.

As shown in FIGS. 1 and 2, optionally, each of the evaporation sub-chambers 2 comprises a shielding unit 8 for shielding the evaporation source 4. The shielding unit 8 may shield the evaporation source 4, which is not in operation, so as to prevent the evaporation material from spreading to undesirable positions.

Optionally, the shielding unit 8 includes: a fixation plate 82 connected to the isolation unit 3 at a side of the evaporation sub-chamber 2; a shielding plate 83 for shielding the evaporation source 4; and a drive shaft 81 for connecting the fixation plate 82 with the shielding plate 83 and driving the shielding plate 83 to move.

For example, the fixation plate 82 of the shielding unit 8 may be fixed to the lower isolation plate 32. The drive shaft 81 may be moved with respect to the fixation plate 82, and the shielding plate 83 may be rotated with respect to the drive shaft 81, without adversely affecting the movement of the upper isolation plate 31. Thus, if the evaporation source 4 is needed to be shielded, then the shielding plate 83 may cover the evaporation source 4 by moving the drive shaft 81 and rotating the shielding plate 83 with respect to the drive shaft 81; if the evaporation source 4 is not needed to be shielded, then the shielding plate 83 may be placed in parallel with the fixation plate 82 by moving the drive shaft 81 adjacent to the fixation plate 82 and rotating the shielding plate 83 with respect to the drive shaft 81. In this way, it can save space and the affection to the evaporation process may be reduced.

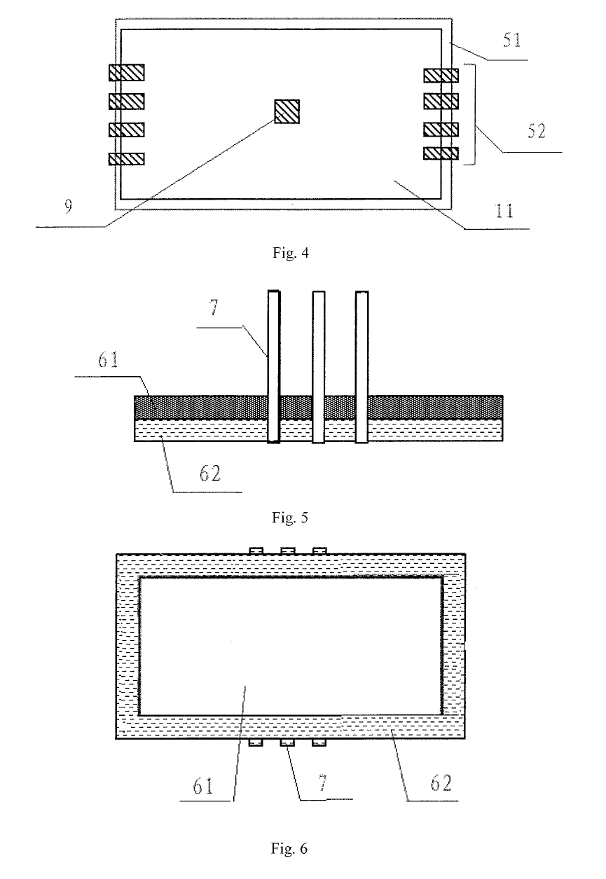

As shown in FIGS. 3 and 4, optionally, the transportation unit 5 includes a magnetic plate 51 for absorbing the substrate 11 to be evaporated, and the magnetic plate 51 is configured to horizontally move the substrate 11 to be evaporated among the plurality of evaporation sub-chambers 2 or vertically move the substrate 11 to be evaporated in each of the evaporation sub-chambers 2.

In this way, the substrate 11 to be evaporated may be moved in the evaporation chamber 1 by means of the magnetic plate 51, so as to position it with respect to a mask unit 6, which will be mentioned below. It should be appreciated for those skilled in the art that the substrate 11 to be evaporated may be absorbed by means of a magnetic field derived from the powered magnetic plate 51.

As shown in FIGS. 3 and 4, optionally, the transportation unit 5 further includes a plurality of supports 52 for assisting the magnetic plate 51 in fixing and moving the substrate 11 to be evaporated, and the supports 52 are arranged at two opposite sides of the magnetic plate 51, so as to support the substrate 11 to be evaporated.

In this way, it may prevent the substrate 11 to be evaporated from falling down during the transportation process. Furthermore, the supports 52 may be detached apart from the substrate 11 to be evaporated after the substrate 11 to be evaporated has been positioned with respect to the mask unit 6, so that the substrate 11 to be evaporated closely contacts with a mask 61, so as to perform the evaporation.

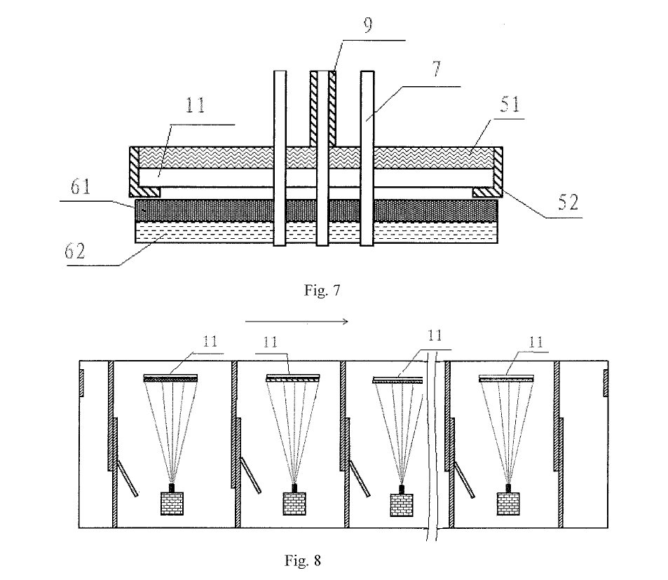

As shown in FIGS. 5, 6, and 7, optionally, the evaporation chamber 1 further includes a mask unit 6 provided between the evaporation sources 4 and the transportation unit 5, the mask unit 6 selectively allows material from the evaporation sources 4 to pass therethrough, so as to form an evaporation pattern on the substrate 11 to be evaporated. The mask unit 6 is arranged at a side of the transportation unit 5 facing to the evaporation sources 4 by means of a supporting rod 7.

In the embodiment of the present disclosure, the mask unit 6 is located above the evaporation sub-chambers 2 and fixed by means of the supporting rod 7. Furthermore, the substrate 11 to be evaporated is positioned with respect to the mask 61 after it enters into the evaporation sub-chamber 2. It should be appreciated that the supporting rod 7 and the transportation unit 5 may be cooperated with each other to position the substrate 11 to be evaporated with respect to the mask 61. For example, positioning holes may be provided in the substrate 11 to be evaporated and the mask 61, respectively. The positioning of the positioning holes may be detected via a camera head, so as to determine whether the positioning process has been completed. It should be appreciated that any positioning processes known to the person skilled in the art are available.

Optionally, the mask unit 6 includes the above-described mask 61 and a cooling plate 62 configured to be in contact with a side of the mask 61 facing to the evaporation sources 4, and the cooling plate 62 is used for cooling the mask 61 and the substrate 11 to be evaporated.

Optionally, the cooling plate 62 includes an opening for exposing a pattern portion of the mask 61. The above-described cooling plate 62 may have circulating cooling water therein, so as to absorb the heat radiated from the evaporation sources 4, thereby preventing the mask 61 and the substrate 11 to be evaporated in close contact with the mask 61 from deformation or any other undesirable defects due to the heat during evaporating.

Optionally, the evaporation chamber 1 further includes a driving unit 12 for driving the transportation unit 5 to move, so as to transport the transportation unit 5 carrying the substrate 11 to be evaporated among the various evaporation sub-chambers 2 in an arrow direction, as shown in FIGS. 1 and 8.

It should be appreciated that the driving unit 12 may be known to the person skilled in the art, and it may include a motor, a drive shaft, etc. The driving unit 12 is not limited thereto, as long as it can be connected to the transportation unit and can control the transportation unit to move in the evaporation chamber 1 in a vertical direction and/or a horizontal direction.

Optionally, the driving unit 12 is connected to a spindle 9 of the magnetic plate 51, so as to drive the magnetic plate 51 to move. The spindle 9 is connected to the driving unit 12, so as to move the magnetic plate 51 in the evaporation chamber 1 in the vertical direction and/or the horizontal direction. It should be appreciated that the driving unit 12 may be connected to magnetic plate 51 in any other suitable manners.

Next, a working process of the evaporation apparatus according to the embodiment of the present disclosure will be described.

First Step: Feeding

Vacuumizing the evaporation chamber 1 and maintaining the vacuum state; opening the enclosing door 10 at the entrance end of the evaporation chamber 1; opening the isolation unit 3 at the left side of the first evaporation sub-chamber 2 at the far left side in FIG. 1, so as to allow the transportation unit 5 carrying the substrate 11 to be evaporated to enter into the first evaporation sub-chamber 2 at the far left side; then, closing the isolation unit 3 so as to close the first evaporation sub-chamber 2 while closing the enclosing door 10 at the entrance end.

Second Step: Positioning

Positioning the substrate 11 to be evaporated carried by the transportation unit 5 with respect to the mask unit 6 supported by the supporting rod 7; in particular, moving the magnetic plate 51 in the evaporation sub-chamber 2 by means of the driving of the spindle 9, while detecting the positioning holes of the substrate 11 to be evaporated and the mask unit 6 via the camera unit and determining whether the positioning process has been completed or not. If the positioning process has been completed, the support 52 is detached apart from the substrate 11 to be evaporated, such that the substrate 11 to be evaporated is made close contact with the mask 61.

Third Step: Evaporating

After the positioning, moving away the shielding unit 8 above the evaporation source 4; in particular, moving the shielding plate 83 above the evaporation source 4 to one side of the fixation plate 82 by means of the drive shaft 81; then, evaporating the substrate 11 to be evaporated, which is located above the evaporation source 4, by means of the evaporation source 4, in this step, the evaporated material passes through the mask 61 and an evaporation pattern is formed on the substrate 11 to be evaporated.

Fourth Step: Moving to Next Evaporation Sub-Chamber

After the evaporating, shielding the evaporation source 4 by means of the shielding plate 83; then, opening the isolation unit 3 at the right side of the evaporation sub-chamber 2, transporting the substrate 11 to be evaporated to the next evaporation sub-chamber by means of driving the transportation unit 5 via the driving unit 12; next, repeating the second step and the third step until the finished substrate exits from the evaporation chamber 1 at an exit end thereof.

The above-described process only refers to the description for evaporating a single substrate to be evaporated. It should be appreciated that as shown FIG. 8, the embodiments of the present disclosure may also evaporate a plurality of substrates 11 to be evaporated in a plurality of evaporation sub-chambers 2. In such a case, the shielding unit 8, the transportation unit 5, the isolation unit 3 in each of the evaporation sub-chambers 2 may be controlled independently, so as to complete the evaporation process of the various substrates 11 to be evaporated.

It will be appreciated that the above-described embodiments are only exemplary embodiments for describing the principle of the present invention, however, the scope of the present invention is not limited hereto. Alternatives and modifications to embodiments of the present disclosure may be made by the skilled person in the art without departing apart from the spirit and scope of the present disclosure, and these alternatives and modifications should fall into the scope of the present invention.

What is claimed is:

1. An evaporation apparatus, comprising an evaporation chamber for evaporating a substrate to be evaporated, wherein the evaporation chamber comprises:
a plurality of isolation units configured to divide the evaporation chamber into a plurality of evaporation sub-chambers;
a plurality of evaporation sources respectively located in the plurality of evaporation sub-chambers; and
a transportation unit arranged opposite to the evaporation sources and configured to move the substrate to be evaporated among the plurality of evaporation sub-chambers.

2. The evaporation apparatus according to claim 1, wherein,
each of the isolation units is configured to be openable and/or closable, so as to allow one evaporation sub-chamber to be communicated with another evaporation sub-chamber adjacent thereto,
the substrate to be evaporated is configured to be moved from the one evaporation sub-chamber to the another evaporation sub-chamber, which is communicated with the one evaporation sub-chamber, via the isolation unit, when the isolation unit is opened, and
the evaporation sub-chambers are isolated from each other when the isolation unit is closed.

3. The evaporation apparatus according to claim 2, wherein,
the isolation unit comprises an upper isolation plate and a lower isolation plate, and
the upper isolation plate and the lower isolation plate are configured to be at least partially overlapped with each other when the isolation unit is closed so as to isolate the one evaporation sub-chamber from the another evaporation sub-chamber adjacent thereto.

4. The evaporation apparatus according to claim 1, wherein,
the transportation unit comprises a magnetic plate for absorbing the substrate to be evaporated, and
the magnetic plate is configured to horizontally move the substrate to be evaporated among the plurality of evaporation sub-chambers or vertically move the substrate to be evaporated in each of the evaporation sub-chambers.

5. The evaporation apparatus according to claim 4, wherein,
the transportation unit further comprises a plurality of supports for assisting the magnetic plate in fixing and moving the substrate to be evaporated, and
the supports are arranged at two opposite sides of the magnetic plate, so as to support the substrate to be evaporated.

6. The evaporation apparatus according to claim 1, wherein,
the evaporation chamber further comprises a mask unit provided between the evaporation sources and the transportation unit, the mask unit being configured for selectively allowing material from the evaporation sources to pass therethrough, so as to form an evaporation pattern on the substrate to be evaporated, and
the mask unit is arranged at a side of the transportation unit facing to the evaporation sources by means of a supporting rod.

7. The evaporation apparatus according to claim 6, wherein,
the mask unit comprises a mask and a cooling plate configured to be in contact with a side of the mask facing to the evaporation sources, the cooling plate being configured for cooling the mask and the substrate to be evaporated.

8. The evaporation apparatus according to claim 7, wherein,
the cooling plate comprises an opening for exposing a pattern portion of the mask.

9. The evaporation apparatus according to claim 3, wherein,
each of the evaporation sub-chambers comprises a shielding unit for shielding the evaporation source.

10. The evaporation apparatus according to claim 9, wherein, the shielding unit comprises:
a fixation plate connected to the isolation unit at a side of the evaporation sub-chamber;
a shielding plate for shielding the evaporation source; and
a drive shaft for connecting the fixation plate with the shielding plate and driving the shielding plate to move.

11. The evaporation apparatus according to claim 4, wherein,
the evaporation chamber further comprises a driving unit for driving the transportation unit to move.

12. The evaporation apparatus according to claim 11, wherein,
the driving unit is connected to a spindle of the magnetic plate, so as to drive the magnetic plate to move.
